(19) United States
(12) Patent Application Publication
(10) Pub. No.: US 2005/0131561 A1
(43) Pub. Date: Jun. 16, 2005

(54) Information handling system including docking station with digital audio capability

(75) Inventors: Jeremy M. Ford, Austin, TX (US); James D. Winden, Georgetown, TX (US)

Correspondence Address: HAYNES AND BOONE, LLP, 901 MAIN STREET, SUITE 3100, DALLAS, TX, 75202, US

(73) Assignee: Dell Products L.P., Round Rock, TX (US)

(21) Appl. No.: 10/736,854

(22) Filed: Dec. 16, 2003

(51) Int. Cl. G06F 17/00; H05K 5/00

(52) U.S. Cl. 700/94; 361/683

(57) ABSTRACT

An information handling system (IHS) is provided which includes a portable portion which is connectable to a docking station. The portable portion and the docking station include respective connectors which connect the portable portion to the docking station. These connectors together form a docking interface. The portable portion includes an audio CODEC having an S/PDIF digital audio output which provides a Sony-Philips Digital Interface (S/PDIF) digital audio signal that is sent across the docking interface to a digital receiver in the docking station. The S/PDIF digital audio signal is converted to analog audio signal by the digital receiver.

### BACKGROUND

The disclosures herein relate generally to information handling systems (IHS's) and more particularly to audio solutions for IHS's with docking stations.

As the value and use of information continue to increase, individuals and businesses seek additional ways to process and store information. One option available to users is information handling systems. An information handling system (IHS) generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Many modern portable IHS's such as laptop computers, notebook computers and personal digital assistants (PDA's) couple to a docking station to provide a user with a full size keyboard, display, mouse and loudspeakers when the portable IHS is operated from a fixed location. Docking stations are known that included an analog sound output to which analog sound signals are routed from the portable IHS through a docking interface between the IHS and the docking station. Unfortunately, such analog audio solutions are susceptible to noise from the processor and power supply along long cable runs. Another significant problem with analog audio in docking stations is presented by ground loops resulting from differences in potential between the portable IHS and the docking station. Although with substantial effort and troubleshooting skill it is possible to minimize such noise and ground loops in a particular IHS design, when changes are made to design a successor model for the IHS, the noise and ground loop problems often must be analyzed and solved anew.

To provide a more noise tolerant interface between the portable IHS and docking station, digital audio signals have been transmitted from the portable IHS across the docking interface to the docking station. Implementations of the Audio CODEC 1997 (AC'97) standard such as AC-Link and the Intel Azalia interface do not address all of the intricacies of a docking implementation. Substantial amounts of software customization are still necessary to insure proper audio performance across the docking interface. 12S is another digital audio standard; however, 12S is not supported in may of today's integrated AC'97 audio CODECs. Universal Serial Bus (USB) is another interface digital standard in current use. However, conventional operating systems do not allow seamless interaction between USB and AC'97 audio devices. For this reason, USB is not a good candidate for usage in a docking environment which is to transport digital audio.

What is needed is a way to transmit digital audio across a docking interface between a portable device and a docking station which provides noise immunity while lending itself to being readily adapted to many different versions of a particular IHS model.

### SUMMARY

Accordingly, in one embodiment, a method of operating an information handling system including a portable portion and a docking station is disclosed. The method includes generating, by the portable portion, a digital audio signal conforming to the S/PDIF standard. The method also includes sending the digital audio signal across a docking interface between the portable portion and a docking station. The method further includes converting the digital audio signal to an analog audio signal and amplifying the analog audio signal.

In another embodiment, an information handling system (IHS) is disclosed which includes a processor and memory coupled to the processor. The IHS also includes glue logic coupled to the processor for facilitating connection of the processor to other devices. The IHS further includes an audio coder decoder coupled to the glue logic. The audio coder decoder includes a S/PDIF digital audio output. The IHS still further includes a docking station having a digital audio receiver coupled to the S/PDIF digital audio output for converting S/PDIF digital audio to analog audio.

### BRIEF DESCRIPTION OF THE DRAWINGS

FIG. 1 is a block diagram of the disclosed information handling system.

### DETAILED DESCRIPTION

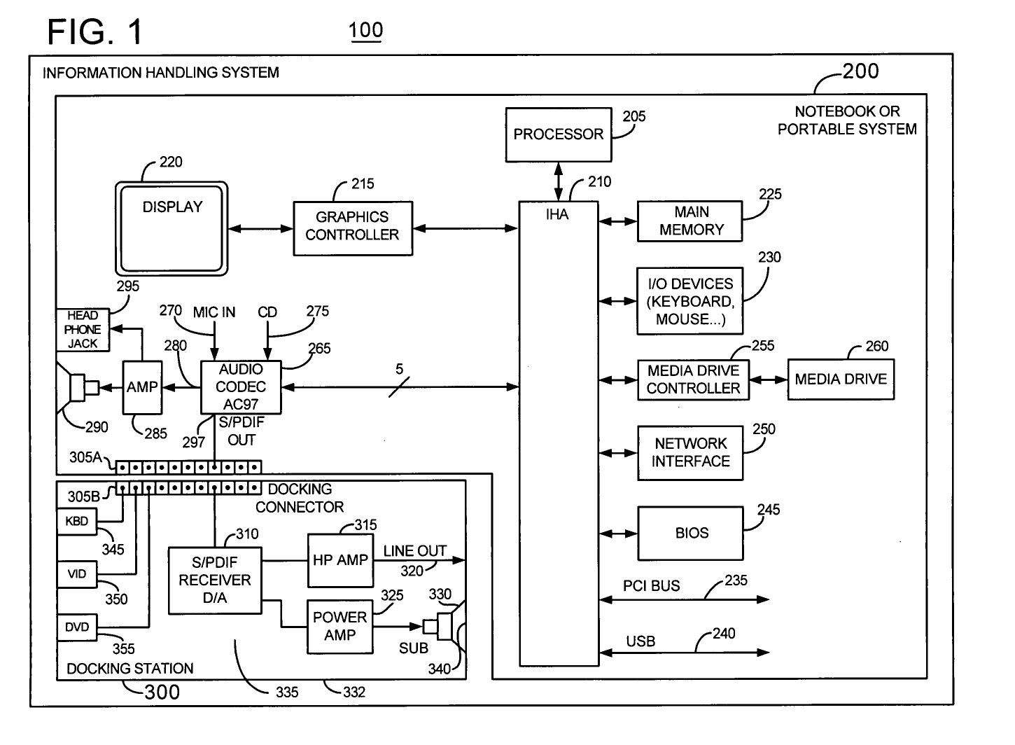

FIG. 1 is a block diagram of the disclosed information handling system (IHS) 100. For purposes of this disclosure, an information handling system (IHS) may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

IHS 100 includes a portable system 200 such as a notebook, laptop, PDA or other handheld system and a docking station 300 as shown in FIG. 1. Portable system 200 includes a processor 205 such as an Intel Pentium series processor or one of many other processors currently available. An Intel Hub Architecture (IHA) chipset 210 provides IHS 100 with glue-logic that connects processor 205 to other components of IHS 100. Chipset 210 carries out graphics/memory controller hub functions and I/O functions. More specifically, chipset 215 acts as a host controller which communicates with a graphics controller 215 coupled thereto. Graphics controller 215 is coupled to a display 220. Chipset 210 also acts as a controller for main memory 225 which is coupled thereto. Chipset 210 further acts as an I/O controller hub (ICH) which performs I/O functions. Input devices 230 such as a mouse, keyboard, and tablet, are also coupled to chipset 210 at the option of the user. An expansion bus 235, such as a Peripheral Component Interconnect (PCI) bus, PCI Express bus, SATA bus or other bus is coupled to chipset 210 as shown to enable IHS 100 to be connected to other devices which provide IHS 100 with additional functionality. A universal serial bus (USB) 240 or other I/O bus is coupled to chipset 210 to facilitate the connection of peripheral devices to IHS 100. System basic input-output system (BIOS) 245 is coupled to chipset 210 as shown. BIOS 245 is stored in nonvolatile memory such as CMOS or FLASH memory. A network interface controller (NIC) 250 is coupled to chipset 210 to facilitate connection of system 100 to other information handling systems. A media drive controller 255 is coupled to chipset 210 so that devices such as media drive 260 can be connected to chipset 210 and processor 205. Devices that can be coupled to media drive controller 260 include CD-ROM drives, DVD drives, hard disk drives and other fixed or removable media drives. IHS 100 includes an operating system which is stored on media drive 260. Typical operating systems which can be stored on media drive 260 include Microsoft Windows XP, Microsoft Windows 2000 and the Linux operating systems. (Microsoft and Windows are trademarks of Microsoft Corporation.)

Portable system 200 includes an audio CODEC 265 coupled to chipset 210. Audio CODEC 265 is compatible with the Audio Codec 1997 (AC97) standard. CODEC 265 includes a microphone input 270 and a CD input 275. CODEC 265 also includes an analog output 280 which is coupled to the input on an audio amplifier 285. Amplifier 285 is coupled to both left and right loudspeakers 290 and to a headphone jack 295. CODEC 265 includes a S/PDIF digital output 297. S/PDIF is an acronym meaning Sony-Philips Digital Interface, a standard protocol for transmitting digital information. S/PDIF output 297 is coupled to one pin of a multi-pin docking connector 305A which includes multiple pins for connecting circuits and devices within portable system 200 to circuits and devices within docking station 300.

Docking station 300 includes a multi-pin docking connector 305B which mates with multi-pin docking connector 305A of portable system 200. The S/PDIF output 297 of CODEC 265 is coupled across docking connector 305A, 305B to a port of a S/PDIF receiver 310. S/PDIF receiver 310 includes a digital to analog (D/A) converter which is coupled to a high power amplifier 315 which drives a LINE OUT output 320 as shown. The LINE OUT output 320 is the main audio output of docking station 300 and can be used to drive high power speakers much larger than the relatively small speakers typically included in portable systems 200. Audio amplifier 315 is a multiple channel amplifier having a number of channels equal to the number of audio channels included in the particular S/PDIF digital signal transmitted from CODEC 265 to S/PDIF receiver 310. Receiver 310 converts the digital audio signal bit stream that it receives into the original multiple analog audio signal channels, for example, left and right analog audio signal channels. Receiver 310 includes a digital to analog converter to accomplish this conversion back to analog. Docking station 300 includes a power amplifier 325 which is coupled to an output of receiver 310 to amplify a bass audio signal received therefrom. Docking station 300 is configured in an enclosure 332 which exhibits a substantially closed volume 335 with the exception of a subwoofer loudspeaker 320 which projects sound through an aperture 340 in enclosure 332. Subwoofer loudspeaker 330 acoustically cooperates with the substantially closed volume 335 to enhance bass audio response. Docking station 300 includes a keyboard connector 345 to enable a keyboard to be coupled from docking station 300 through connector 305A-305B to portable system 200. Docking station 300 also includes a display or video connector 350 to enable a standalone display to be coupled to portable system 200 via docking station 300. Docking station 300 further includes a media drive connector 355, for example a DVD or CD drive connector, to enable an external media drive to be connected to portable system 200 via docking station 300.

Although illustrative embodiments have been shown and described, a wide range of modification, change and substitution is contemplated in the foregoing disclosure and in some instances, some features of an embodiment may be employed without a corresponding use of other features. Accordingly, it is appropriate that the appended claims be construed broadly and in manner consistent with the scope of the embodiments disclosed herein.

1. An information handling system including:
a processor;
memory coupled to the processor;
glue logic coupled to the processor for facilitating connection of the processor to other devices;
an audio coder decoder coupled to the glue logic and including a Sony-Philips Digital Interface (S/PDIF) digital audio output; and
a docking station including a digital audio receiver coupled to the S/PDIF digital audio output for converting S/PDIF digital audio to analog audio.

2. The information handling system of claim 1 including a first docking connector to which the S/PDIF digital audio output is coupled.

3. The information handling system of claim 2 including a second docking connector to which the digital audio receiver is coupled.

4. The information handling system of claim 3 wherein the first docking connector is connected to the second docking connector to couple the S/PDIF digital audio output to the digital audio receiver.

5. The information handling system of claim 1 wherein the digital audio receiver includes an analog output.

6. The information handling system of claim 5 including a first power amplifier is coupled to the analog output.

7. The information handling system of claim 6 including a second power amplifier coupled to the analog output.

8. The information handling system of claim 7 including a subwoofer coupled to the second power amplifier.

9. The information handling system of claim 8 wherein the docking station includes a substantially closed volume having an aperture.

10. The information handling system of claim 9 wherein the subwoofer is situated in the aperture to project sound therethrough.

11. A method of operating an information handling system including a portable portion and a docking station, the method comprising:
generating, by the portable portion, a digital audio signal conforming to a Sony-Philips Digital Interface (S/PDIF) standard;
sending the digital audio signal across a docking interface between the portable portion and a docking station;
converting the digital audio signal to an analog audio signal; and
amplifying the analog audio signal.

12. The method of claim 11 wherein the docking interface includes a first connector to which the digital audio signal is provided.

13. The method of claim 12 wherein the docking interface includes a second connector.

14. The method of claim 13 including connecting the first connector to the second connector.

15. The method of claim 14 including performing a digital to analog conversion on the digital audio signal after it passes from the first connector to the second connector of the docking interface, thus converting the digital analog signal to an analog audio signal.

16. The method of claim 15 including amplifying the analog audio signal by a first audio amplifier thus providing a first amplified analog audio signal.

17. The method of claim 16 including providing the first amplified analog audio signal to a line out output of the docking station.

18. The method of claim 16 including amplifying the analog audio signal by a second audio amplifier thus providing an second amplified analog audio signal.

19. The method of claim 18 including providing the second amplified analog audio signal to a subwoofer loudspeaker.

20. The method of claim 19 wherein the docking station exhibits a substantially closed volume.

21. Apparatus for operating a portable information handling system (IHS) comprising:
a docking station coupled to the IHS;
means for generating a digital audio signal conforming to a Sony-Philips Digital Interface (S/DIF) standard;
means for sending the digital audio signal across a docking interface between the IHS and the docking station;
a converter for converting the digital audio signal to an analog audio signal; and
means for amplifying the audio analog signal.
